(19) United States
(12) Patent Application Publication
(10) Pub. No.: US 2020/0203486 A1
(43) Pub. Date: Jun. 25, 2020

(54) METHOD FOR MANUFACTURING DOPED GRAPHENE THIN FILM HAVING MESOPOROUS STRUCTURE USING FLASH LAMP AND GRAPHENE THIN FILM WITH MESOPORE MANUFACTURED THEREBY

(71) Applicant: Korea Advanced Institute of Science and Technology, Daejeon (KR)

(72) Inventors: Sung-Yool CHOI, Daejeon (KR); Jun-Hwe CHA, Daejeon (KR); Il-Doo KIM, Daejeon (KR)

(73) Assignee: Korea Advanced Institute of Science and Technology, Daejeon (KR)

(21) Appl. No.: 16/720,468

(22) Filed: Dec. 19, 2019

(30) Foreign Application Priority Data
Dec. 20, 2018 (KR) 10-2018-0165866

(51) Int. Cl. H01L 29/16; C01B 32/194; C01B 32/184

(52) U.S. Cl. CPC H01L 29/1606; C01B 32/184; C01B 32/194

(57) ABSTRACT

Provided is a method for manufacturing a doped graphene thin film having a mesoporous structure using a flash lamp, which comprises: a step of coating a mixture solution of a doping element source-containing material comprising a doping element and graphene oxide on a substrate; and a step of irradiating light to the coated mixture solution using a flash lamp, thereby carrying out reduction of the graphene oxide and doping of the doping element at the same time.

### CROSS-REFERENCE TO RELATED APPLICATIONS

This application claims the benefit under 35 USC § 119(a) of Korean Patent Application No. 10-2018-0165866 filed on Dec. 20, 2018 in the Korean Intellectual Property Office, the entire disclosure of which is incorporated herein by reference for all purposes.

### TECHNICAL FIELD

The present disclosure relates to a method for manufacturing a doped graphene thin film having a mesoporous structure using a flash lamp and a graphene thin film having a mesoporous structure manufactured thereby. More particularly, it relates to a method for manufacturing a doped graphene thin film having a mesoporous structure using a flash lamp capable of reducing and doping graphene oxide at the same time without additional vacuum systems, and graphene thin film having a mesoporous structure manufactured thereby.

### BACKGROUND ART

Graphene refers to a planar single-layer structure of carbon atoms in a two-dimensional (2D) lattice. It is the basic structural element of all other allotropes, including graphite. That is to say, graphene can be the basic structure of 0-dimensional fullerene, 1-dimensional nanotube or 3-dimensional graphite. In 2004, Novoselev et al. reported that they obtained free-standing graphene single layers on a SiO₂/Si substrate. It was experimentally discovered through mechanical exfoliation.

In the processing and application of graphene, the prevention of aggregation of graphene is of great importance. Graphene in a sheet form with a thickness of one atom tends to aggregate due to high surface energy. This makes the direct manufacturing of graphene, especially in a hydrophilic solvent, very difficult. For this reason, graphene is manufactured through a rather complicated process by the Hummer's method of preparing graphene oxide (GO) first and then reducing the same (prior art 1). In addition to the preparation of graphene oxide through the oxidation process, the organic solvent-based graphene preparation of exfoliating graphite in an organic solvent such as N-methylpyrrolidone, γ-butyrolactone, etc. and dispersing the obtained graphene is known (prior art 2). In the organic solvent-based method, the aggregation of graphene is prevented using the energy between the graphene and the organic solvent, which is similar to the energy between graphene sheets. However, the size of the graphene obtained from the prior arts 1 and 2 is only in the level of nanometers to micrometers. Therefore, the prior arts 1 and 2 are not suitable for the manufacturing of large-area graphene.

Korean Patent Publication No. 10-2010-0136576 discloses a process of preparing a reduced graphene oxide film (rGO) by reducing a graphene oxide (GO) film through a special reduction process.

And, Al-Harmry et al. disclose a process of reducing a graphene oxide solution using IPL (intense pulsed light) in CARBON 10770, etc.

However, because doping is necessary to use the graphene as a semiconductor material, development of a process whereby doping and reduction can be carried out at the same time is necessary. With regard to conventional approaches for doping, GO has been kept in a vacuum system at an elevated temperature for several hours to achieve reduction and doping. Therefore, it is highly required to readily reduce and dope GO with no need of addition vacuum system. In addition, a technique for manufacturing a graphene thin film having a high specific surface area having a mesoporous structure simultaneously with doping/reducing has not been disclosed.

### DISCLOSURE

### Technical Problem

The present disclosure is directed to providing a process whereby reduction and doping of graphene oxide having a mesoporous structure can be carried out at the same time and a graphene thin film synthesized thereby.

### Technical Solution

The present disclosure provides a method for manufacturing a doped graphene thin film having a mesoporous structure using a flash lamp, which includes: a step of coating a mixture solution of a doping element source-containing material containing a doping element and graphene oxide on a substrate; and a step of irradiating light to the coated mixture solution using a flash lamp, thereby carrying out reduction of the graphene oxide and doping of the doping element at the same time.

In an exemplary embodiment of the present disclosure, the doping element source-containing material is an oxide of the doping element source.

In an exemplary embodiment of the present disclosure, the light is irradiated in a pulsed manner.

In an exemplary embodiment of the present disclosure, the doping element source-containing oxide forms a bond between the carbon of the graphene and the doping element as it is doped by the light irradiation.

In an exemplary embodiment of the present disclosure, the reduction and doping by the light irradiation are carried out under atmospheric condition.

In an exemplary embodiment of the present disclosure, the method for manufacturing a doped graphene thin film with a mesoporous structure using a flash lamp further comprises, after the light irradiation carried out under atmospheric condition, a step of removing the oxide of the doped doping element source from the surface of the graphene thin film, and the light is irradiated repeatedly multiple times with intervals of several to hundreds of milliseconds.

The present disclosure provides a doped graphene thin film manufactured by the method described above.

In an exemplary embodiment of the present disclosure, the graphene thin film contains a doped doping element inside the graphene thin film, and the oxide of the doped element does not exist on the surface of the graphene thin film.

### Advantageous Effects

According to the present disclosure, the reduction and doping of graphene oxide can be carried out at the same time using a flash lamp. Accordingly, graphene can be manufactured economically because the reduction and doping of graphene oxide can be readily carried out at quickly in a solution. In addition, by repeating the heating for a short time, it is possible to produce a graphene thin film having a high specific surface area of mesoporous structure.

### BRIEF DESCRIPTION OF DRAWINGS

The patent or application file contains a least one drawing executed in color. Copies of this patent or patent application publication with color drawing(s) will be provided by the Office upon request and payment of the necessary fee.

FIG. 1 shows a block diagram of a method for manufacturing a doped graphene thin film according to an exemplary embodiment of the present disclosure.

FIG. 2 shows an optical image of a graphene oxide thin film including BA coated on a glass substrate prepared according to the present embodiment.

FIG. 3A shows C 1s XPS analysis results before IPL exposure and FIG. 3B after IPL exposure, and FIGS. 3C and 3D show C 1s XPS data after exposure to IPL flash light of GO including BA (B@rGO) on different light energies.

FIG. 4A shows B 1s XPS data before IPL exposure, FIG. 4B after IPL exposure of GO that did not contain BA, and FIGS. 4C and 4D after exposure to IPL light of GO that contained BA on different light energies.

FIG. 5A to 5C show a heating rate and the result of BET data analysis accordingly.

FIG. 6A to 6C show scanning electron microscope images of photothermally treated samples of GO, which do not include GO and BA, and photothermally treated samples of GO, including BA, respectively.

FIGS. 7A and 7B show a result of comparing the NO₂ gas detection characteristics.

### BEST MODE

Hereinafter, specific exemplary embodiments of the present disclosure are described in detail referring to the attached drawings. In the attached drawings, it should be noted that like numerals refer to like elements. Also, a detailed description of a generally known function and structure will be avoided lest it should obscure the subject matter of the present disclosure. For the same reason, some elements in the attached drawings are exaggerated, omitted or illustrated schematically.

Also, throughout the present disclosure, the term “include” does not preclude the existence of other elements unless clearly stated otherwise. In addition, throughout the present disclosure, “on” does means the presence above or below an object and does not necessarily mean the presence on the upper side based on the gravitational direction.

The present disclosure provides a method of inducing reduction and doping of graphene oxide through an optical method, particularly by reducing an oxide.

Therefore, according to the present disclosure, a semiconductor material based on doped graphene can be manufactured in a more economical and effective manner. In the present specification, a doped graphene thin film refers to a reduced graphene oxide thin film doped with a desired doping element. In the present specification and drawings, GO refers to unreduced graphene oxide with oxygen bound on the surface, and rGO refers to reduced graphene oxide with the oxygen functional groups removed from the surface through reduction.

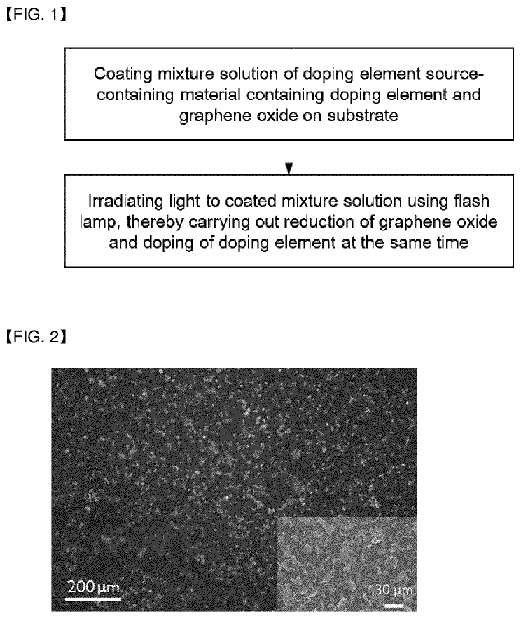

FIG. 1 shows a block diagram of a method for manufacturing a doped graphene thin film according to an exemplary embodiment of the present disclosure.

Referring to FIG. 1, a method for manufacturing a doped graphene thin film according to the present disclosure includes: a step of coating a mixture solution of a doping element source-containing material containing a doping element and graphene oxide on a substrate; and a step of irradiating light to the coated mixture solution in the air using a flash lamp, thereby carrying out reduction of the graphene oxide and doping of the doping element at the same time with no need of additional vacuum systems.

Whereas the conventional doping of rGO (reduced graphene oxide) is conducted by heat treatment at high temperature under inert gas atmosphere such as Ar or N₂ for a long time or by hydrothermal synthesis or solvent thermal synthesis at high pressure and relatively low temperature, the present disclosure has greatly improved process simplicity by conducting reduction and doping of GO at the same time by exposing light (IPL, intense pulsed laser) from a flash lamp for a very short time of millisecond levels without need of additional vacuum systems.

In an exemplary embodiment of the present disclosure, the doping element source-containing material is one that is mixed easily with a graphene oxide aqueous solution. Specifically, it is an oxide of the doping element source. That is to say, according to the present disclosure, the doping element source material in oxide state makes dispersion of graphene oxide easily in an aqueous solution. As it is reduced by the IPL light simultaneously with graphene oxide, the doping element is diffused into the graphene, followed by substitutional doping.

Hereinafter, an exemplary embodiment of the present disclosure is described through examples. However, the scope of the present disclosure is not limited by the substances described in the examples.

### EXAMPLE

First, after adding 20 mg of boronic acid, as a boron doping source in oxide form, to 5 mg of GO dispersed in 2 mL of deionized water (DI), the mixture was sonicated for 30 minutes.

Then, an alumina or glass substrate was drop-coated and then dried at 50° C. for about 20 minutes. The boronic acid-containing graphene oxide (GO) film was exposed to a flash lamp (IPL, intense pulsed light).

Then, in order to remove B₂O₃ produced during the doping and reduction under atmospheric condition from undoped boronic acid, the B₂O₃ was washed off by immersing sequentially in a basic NaOH solution and DI. FIG. 2 shows an optical image of a graphene oxide thin film doped with boron (B@rGO) coated on a glass substrate prepared according to the present embodiment.

Experimental Result

First, XPS analysis was conducted to investigate whether the boronic acid (BA)-containing GO (BA@GO) was reduced by exposure to the flash lamp (IPL).

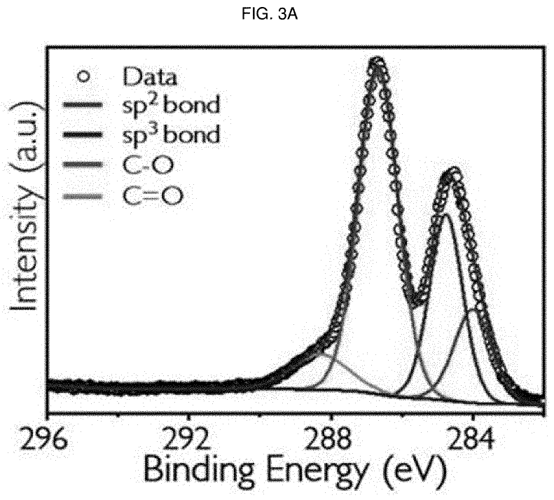

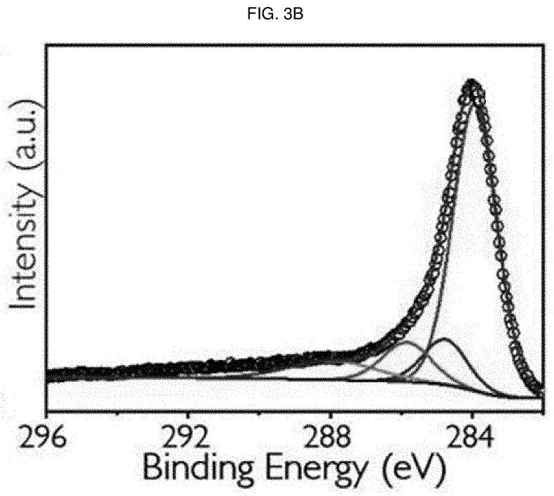

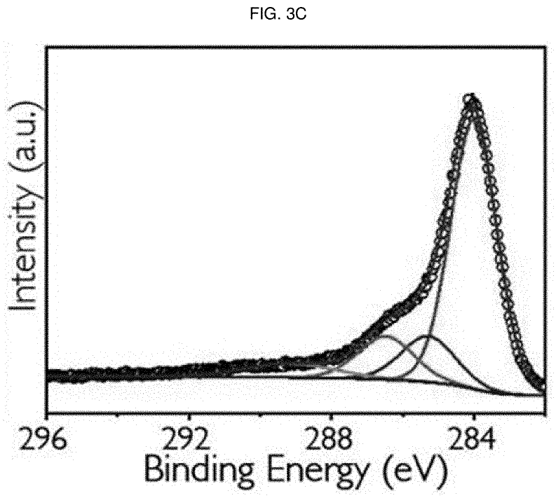

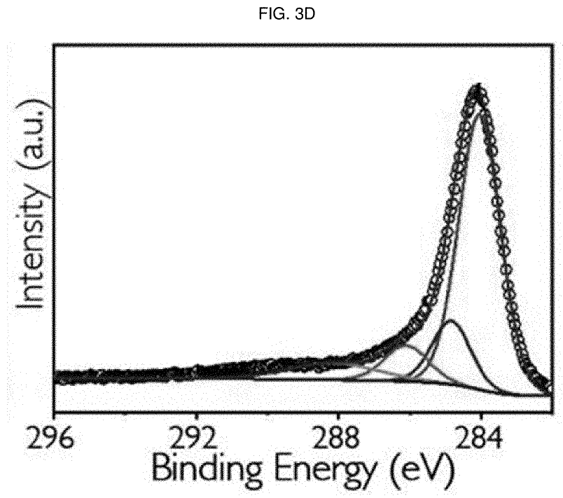

FIG. 3A shows C 1s XPS analysis results before IPL exposure and FIG. 3B after IPL exposure, and FIGS. 3C and 3D show C 1s XPS data after exposure to IPL flash light of GO including BA (B@rGO) on different light energies.

Referring to FIGS. 3A and FIG. 3B, it can be seen that most of the C=0 bonds that had existed on the graphene oxide before the light exposure disappeared after the light exposure, suggesting that reduction was carried out successfully. Referring to FIGS. 3C and FIG. 3D, higher energy was induced with longer irradiation time and further reduction was confirmed from the decrease in intensity of C—O. From the data in FIGS. 3A to 3D, successful reduction was performed even with GO including BA (B@rGO).

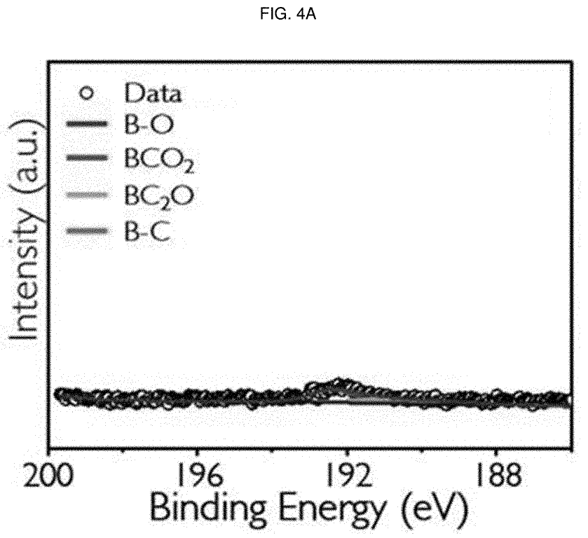

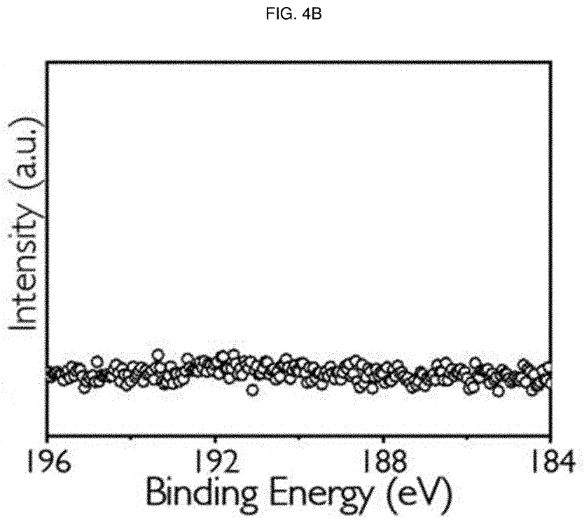

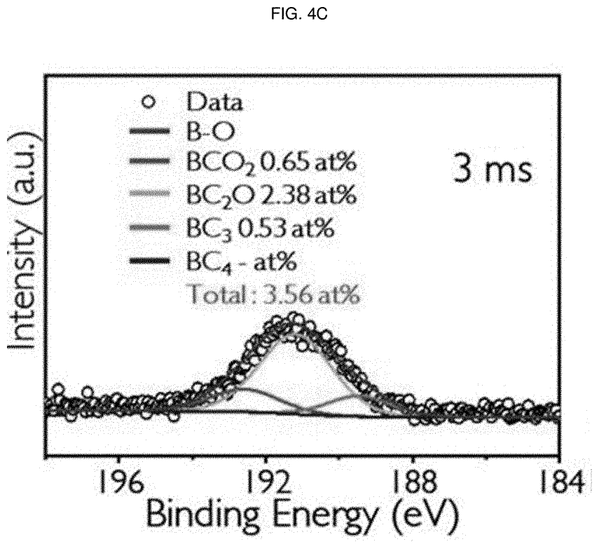

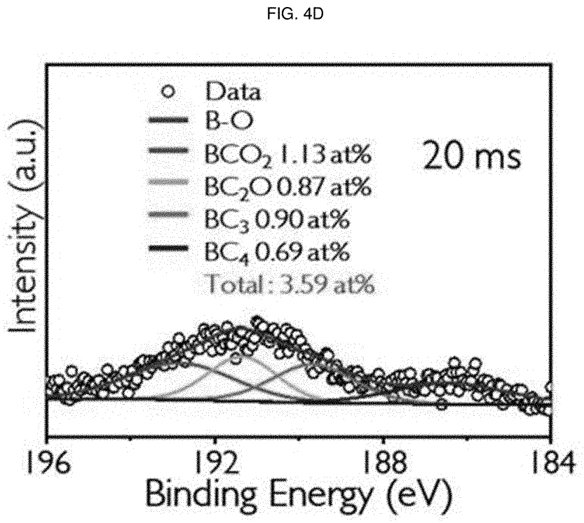

FIG. 4A shows B 1s XPS data before IPL exposure, FIG. 4B after IPL exposure of GO that did not contain BA, and FIGS. 4C and 4D after exposure to IPL light of GO that contained BA on light energies.

As shown in FIG. 4B, when BA was not included, no boron related binding was present. On the contrary, in the case of the sample including BA such as 4C, it can be seen that B—C bond-related (BCO₂, BC₂O, BC₃) peaks, which are bonds between the doping element and the carbon, were generated through IPL treatment. In the case of 4D with higher energy, it was confirmed that BC₄ binding can be produced additionally. Through this, we found that B doping was successful carried out through IPL processing in milliseconds (ms) in the air.

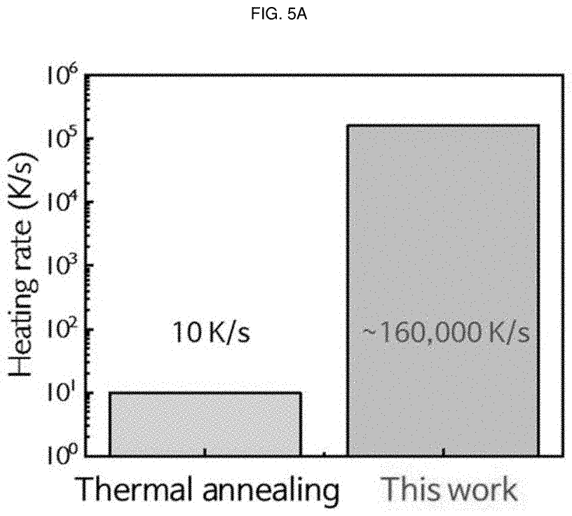

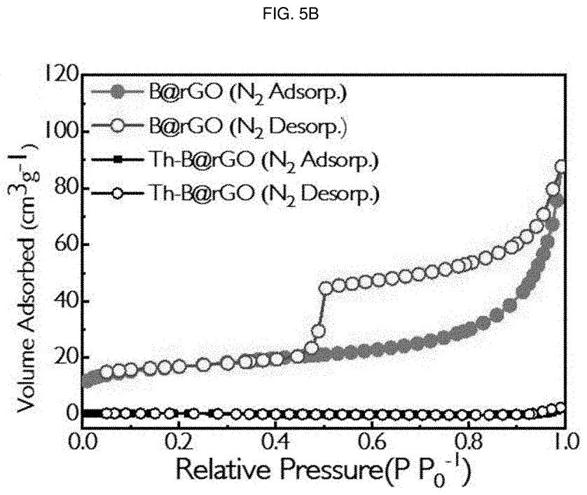

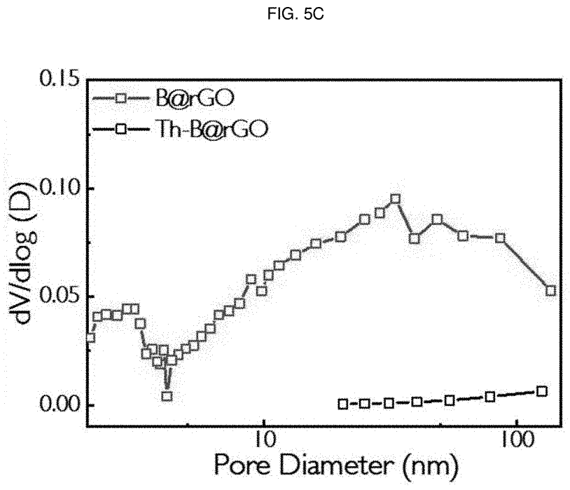

FIGS. 5A to 5C show a heating rate and the result of BET data analysis accordingly

As shown in FIG. 5A, the photothermal treatment according to the present invention can exhibit a much faster heating rate than the conventional heat treatment, so that a vacuum system is not required unlike doping through a general heat treatment process. Therefore, the process is completed quickly in the air, and such rapid photothermal treatment increases the instantaneous pressure between the GO sheets, which not only leads to peeling of each sheet, but also forms micro pores uniformly. As a result, graphene having a high specific surface area and doped with hetero atoms can be synthesized from graphene oxide.

FIG. 5B shows the BET data of B-doped rGO obtained through light heat treatment and general heat treatment. In the photothermally treated samples shown in red, hysteresis curves occur during the adsorption and desorption of N₂ gas at partial pressures from 0.5 to 1.0. This suggests that a lot of fine pores are distributed in the material. In addition, the numerical comparison of the specific surface area confirmed that the specific surface area of the photothermally treated sample (60.59 m²g⁻¹) was significantly improved compared to the heat treated sample (1.76 m²g⁻¹). In FIG. 5C, it was confirmed that only the mesopore of 2˜50 nm in the light heat treatment sample.

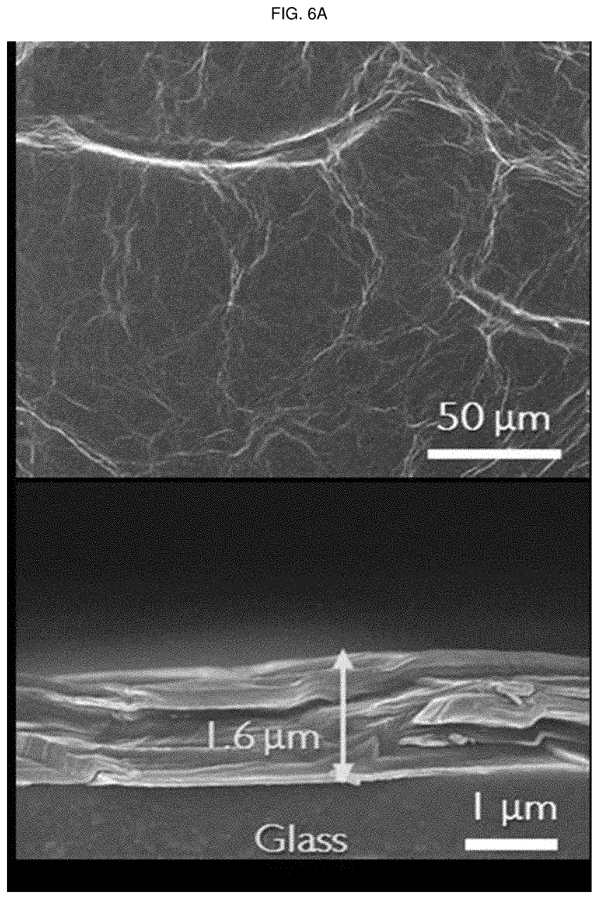

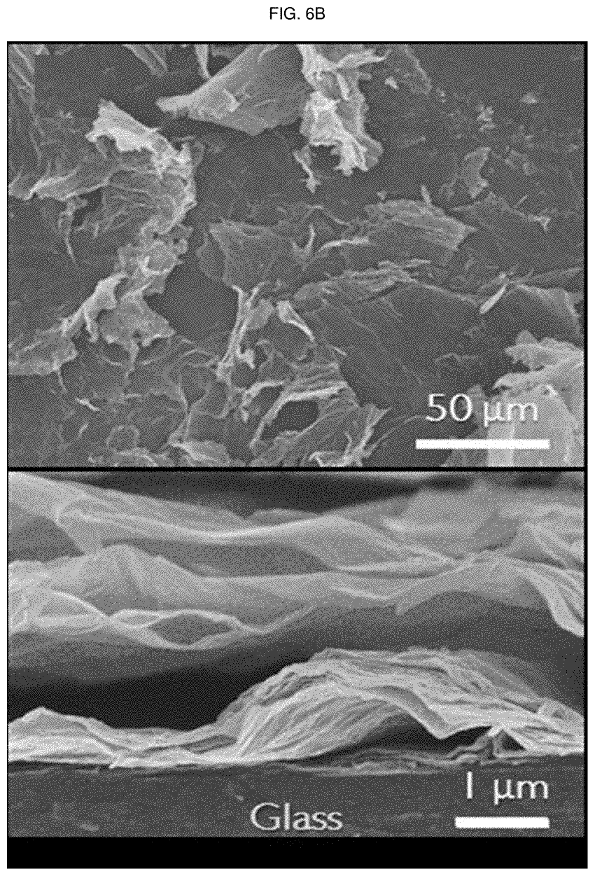

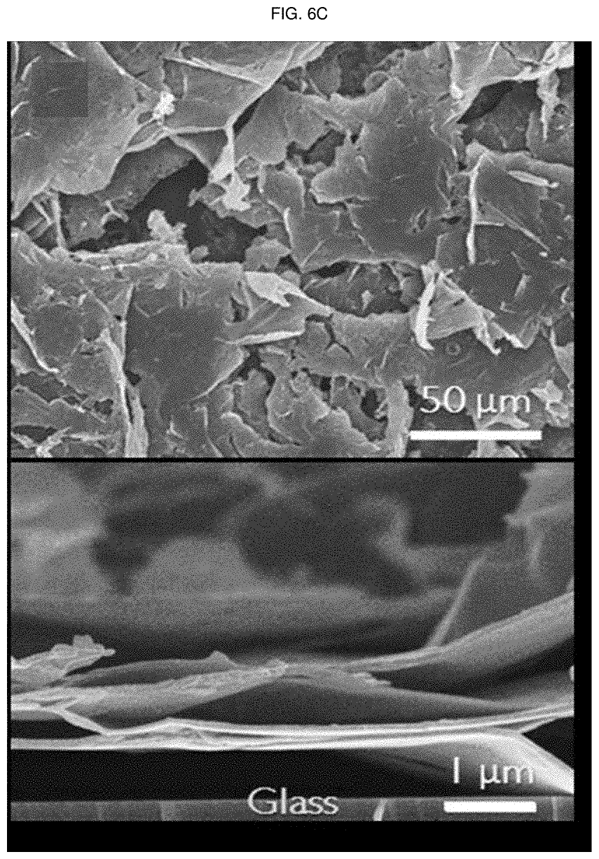

FIGS. 6A to 6C show scanning electron microscope images of photothermally treated samples of GO, which do not include GO and BA, and photothermally treated samples of GO, including BA, respectively.

According to FIGS. 6A to 6C, it was confirmed that many surface pores and peelings occurred in the photothermally treated sample.

Boron doped graphene is known to further improve the NO₂ sensing characteristics compared to undoped graphene. Accordingly, in addition to the component analysis, compared to the boron doped graphene according to the present invention compared to the conventional undoped graphene rGO (reduced graphene oxide) NO₂ gas detection characteristics.

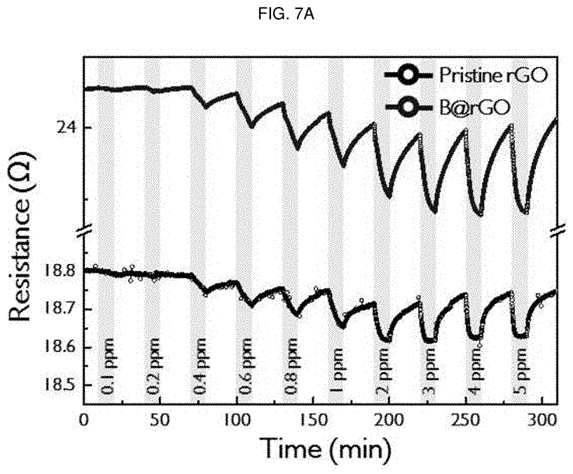

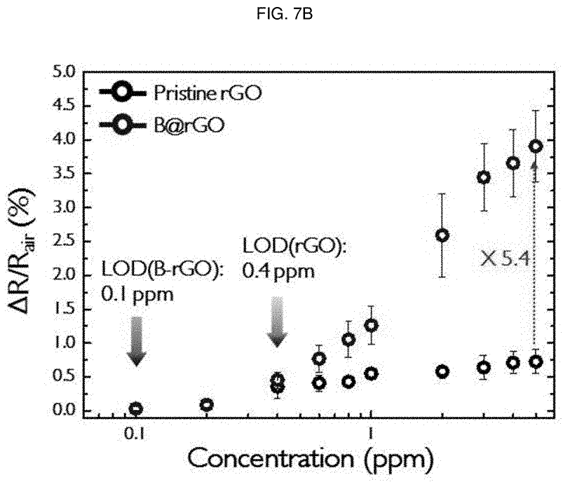

FIGS. 7A and 7B show a result of comparing the NO₂ gas detection characteristics.

Referring to FIGS. 7A and 7B, air was repeatedly exposed for 20 minutes after 10 minutes of exposure at each concentration by varying the NO₂ concentration between 0.1 and 5 ppm in a relative humidity of 80%. As a result, it was confirmed that the boron-doped reduced graphene (B@rGO) sample according to the present invention showed higher sensitivity than the conventional reduced graphene oxide (rGO). As a result, not only reduction and simultaneous doping of GO through IPL, but also a significant improvement in the specific surface area was confirmed.

1. A method for manufacturing a doped graphene thin film having a mesoporous structure using a flash lamp, which comprises:
a step of coating a mixture solution of a doping element source-containing material comprising a doping element and graphene oxide on a substrate; and
a step of irradiating light to the coated mixture solution using a flash lamp, thereby carrying out reduction of the graphene oxide and doping of the doping element at the same time.

2. The method for manufacturing a doped graphene thin film having a mesoporous structure using a flash lamp according to claim 1, wherein the doping element source-containing material is an oxide of the doping element source.

3. The method for manufacturing a doped graphene thin film having a mesoporous structure using a flash lamp according to claim 1, wherein the light is irradiated in a pulsed manner.

4. The method for manufacturing a doped graphene thin film having a mesoporous structure using a flash lamp according to claim 2, wherein the doping element source-containing oxide forms a bond between the carbon of the graphene and the doping element as it is doped by the light irradiation.

5. The method for manufacturing a doped graphene thin film having a mesoporous structure using a flash lamp according to claim 1, wherein the reduction and doping by the light irradiation are carried out under atmospheric condition.

6. The method for manufacturing a doped graphene thin film having a mesoporous structure using a flash lamp according to claim 5, which comprises, after the light irradiation carried out under atmospheric condition without any additional vacuum process, a step of removing the oxide of the doped doping element source from the surface of the graphene thin film.

7. The method for manufacturing a doped graphene thin film having a mesoporous structure using a flash lamp according to claim 1, wherein the light is irradiated repeatedly multiple times with intervals of several to hundreds of milliseconds.

8. The method for manufacturing a doped graphene thin film having a mesoporous structure using a flash lamp according to claim 1, wherein the graphics thin film has a mesopore structure of 2 to 50 nm.

9. A doped graphene thin film having a mesoporous structure manufactured by the method according to claim 1.

10. The doped graphene thin film according to claim 9, wherein the graphene thin film comprises a doped doping element inside the graphene thin film, and the oxide of the doped element does not exist on the surface of the graphene thin film.
